(19) United States
(12) Patent Application Publication
(10) Pub. No.: US 2008/0135999 A1
(43) Pub. Date: Jun. 12, 2008

(54) PACKAGE DEVICE

(76) Inventor: Wu-Der Yang, Tao-Yuan City (TW)

Correspondence Address: NORTH AMERICA INTELLECTUAL PROPERTY CORPORATION, P.O. BOX 506, MERRIFIELD, VA, 22116, US

(21) Appl. No.: 11/750,304

(22) Filed: May 17, 2007

(30) Foreign Application Priority Data
Dec. 7, 2006 (TW) 095145657

(51) Int. Cl. H01L 23/02

(52) U.S. Cl. 257/680; 438/122; 257/E23.18

(57) ABSTRACT

The present invention relates to a package device including a first substrate, a plurality of first chips positioned on the first substrate, a second substrate positioned on the first substrate, a second chip positioned on the second substrate, an adhesive layer positioned on the second chip, and a heat spreader positioned above the first substrate, the first chips, the second substrate, and the adhesive layer, wherein the heat spreader has a plurality of openings for cold air to flow into the package device and generate convection with hot air inside the package device in order to cool down the package device.

### BACKGROUND OF THE INVENTION

1. Field of the Invention

The present invention relates to a package device, and more particularly, to a package device with a heat spreader having a plurality of openings for cold air to flow into the package device and generate convection with hot air inside the package device during operation period of the package device in order to cool down the inside of the package device in operation.

2. Description of the Prior Art

Please refer to FIG. 1. FIG. 1 shows a schematic, cross-sectional diagram illustrating a conventional Fully Buffered Dual In-line Memory Module (FBDIMM). As shown in FIG. 1, the conventional FBDIMM 100 includes a printed circuit board 102, a plurality of memory chips 104 and an advanced memory buffer (AMB) substrate 106 positioned on the printed circuit board 102, an AMB chip 108 positioned on the AMB substrate 106, a heat-spreading adhesive layer 110 positioned on the AMB chip 108, and a heat spreader 112, wherein the heat spreader 112 is connected and fixed with the AMB chip 108 via the heat-spreading adhesive layer 110, but the heat spreader 112 is not in touch with the memory chips 104.

In appearance, the heat spreader 112 has a prominent area 114 and a flat area 116, wherein the prominent area 114 is positioned directly above the AMB substrate 106 and the heat-spreading adhesive layer 110, and the flat area 116 is positioned directly above the printed circuit board 102 and the memory chips 104. The heat spreader 112 covers the memory chips 104 and the AMB chip 108 in a sealed environment like a lid, and heat generated by the memory chips 104 and the AMB chip 108 during operation can only be transmitted via air transmission and the heat-spreading adhesive layer 110 to the heat spreader 112. Therefore, the heat spreader 112 in the prior art is not able to spread heat efficiently.

### SUMMARY OF THE INVENTION

The present invention discloses a package device with a heat spreader having a plurality of openings for cold air to flow into the package device and generate convection with hot air inside the package device in order to cool down the inside of the package device in operation.

According to the claims, the present invention provides a package device comprising a chip module and a heat spreader, wherein the chip module comprises a first substrate, a plurality of first chips positioned on the first substrate, a second substrate positioned on the first substrate, a second chip positioned on the second substrate, an adhesive layer positioned on the second substrate, and a heat spreader positioned above the first substrate, the first chips, the second substrate, and the adhesive layer, wherein a chamber is composed of the heat spreader and the first substrate, and the chamber contains the first chips, the second substrate, and the second chip, and the heat spreader has a plurality of openings positioned above the first chips for cold air to flow into the chamber and generate convection with hot air inside the chamber in order to cool down the first chips and the second chip.

According to the claims, the present invention further provides an FBDIMM, comprising a printed circuit board, a plurality of memory chips positioned on the printed circuit board, an AMB substrate positioned on the printed circuit board, an AMB chip positioned on the AMB substrate, a heat-spreading adhesive layer, positioned on the AMB chip, and a heat spreader having a prominent area and a flat area, the prominent area being positioned above the AMB substrate and the heat-spreading adhesive layer, and the flat area being positioned above the printed circuit board and the memory chips, and the heat spreader being connected to the AMB chip via the heat-spreading adhesive layer, wherein a chamber is composed of the heat spreader and the printed circuit board, and the chamber contains the memory chips, the AMB substrate, and the AMB chip, characterized in that: the heat spreader has a plurality of first openings and a plurality of second openings, the first openings and the second openings being parallel, and the first openings and the second openings are positioned above the memory chips.

According to the claims, the present invention further provides a heat spreading method for a package device, comprising providing a chip module and a heat spreader, and covering the heat spreader over outside the chip module, wherein a plurality of openings are formed on the heat spreader, for cold air to flow into the package device and generate convection with hot air inside the package device in order to cool down the package device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a schematic, cross-sectional diagram illustrating a conventional Fully Buffered Dual In-line Memory Module (FBDIMM).

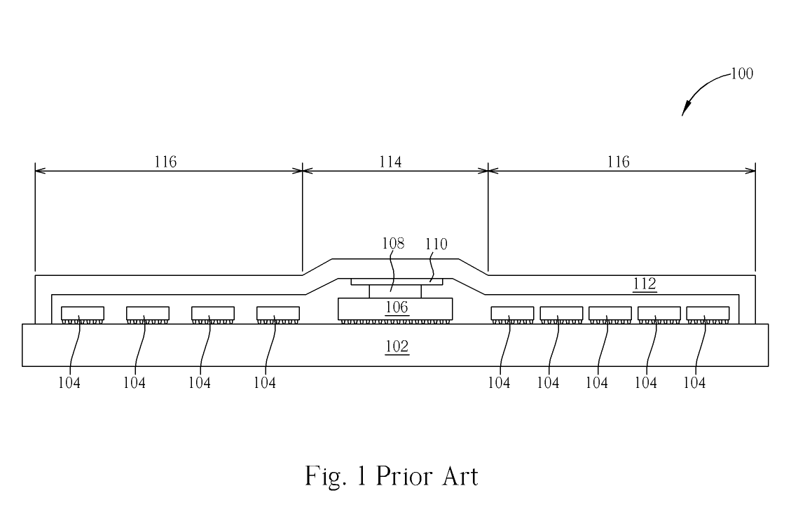

FIG. 2 shows a schematic, cross-sectional diagram illustrating a package device in accordance with a first preferred embodiment of the present invention.

FIG. 3 shows a three-dimensional diagram of the heat spreader shown in FIG. 2.

FIG. 4 shows a schematic, cross-sectional diagram illustrating a package device in accordance with a second preferred embodiment of the present invention.

### DETAILED DESCRIPTION

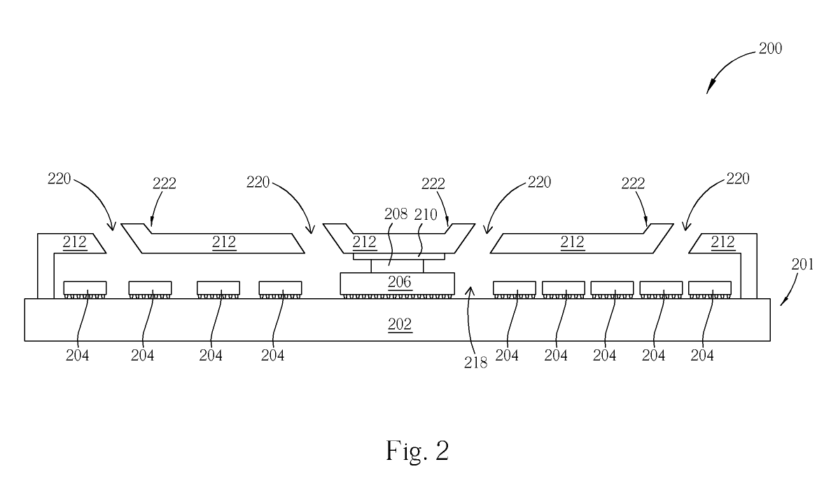

Please refer to FIG. 2. FIG. 2 shows a schematic, cross-sectional diagram illustrating a package device in accordance with a first preferred embodiment of the present invention. As shown in FIG. 2, the package device 200 includes a chip module 201 and a heat spreader 212, wherein the chip module 201 includes a first substrate 202, a plurality of first chips 204 and a second substrate 206 positioned on the first substrate 202, a second chip 208 positioned on the second substrate 206, and an adhesive layer 210 positioned on the second chip 208, and the heat spreader 212 is positioned above the first substrate 202, the first chips 204, the second substrate 206, and the adhesive layer 210. The heat spreader 212 is connected to the second chip 208 via the adhesive layer 210, but the heat spreader 212 is not in touch with the first chips 204.

The chip module 201 can be a Fully Buffered Dual In-line Memory Module (FBDIMM). The first substrate 202 can be a printed circuit board. The first chips 204 can be Dynamic Random Access Memory (DRAM) chips. The second substrate 206 can be an advanced memory buffer (AMB) substrate. The second chip 208 can be an AMB chip. The first chip 204 and the second substrate 206 can be electrically connected to the first substrate 202 via a ball grid array (BGA) package, and the second chip 208 can be electrically connected to the second substrate 206 via a Flip Chip BGA package, but this is not a limitation of the present invention. Furthermore, the adhesive layer 210 can be a heat-spreading adhesive, and materials of the heat spreader 212 can be aluminum or copper.

Additionally, a chamber 218 is composed of the heat spreader 212 and the first substrate 202, and the chamber 218 contains the first chips 204, the second substrate 206, and the second chip 208. The present invention is characterized in that the heat spreader 212 has a plurality of openings 220 positioned above the first chips 204, and the openings 220 are used for cold air to flow into the chamber 218 and generate convection with hot air inside the chamber 218 in order to cool down the first chips 204 and the second chip 208.

The present invention is further characterized in that the same side of each opening 220 has a protruding structure 222. The protruding structure 222 is formed during fabrication of the opening 220 by a punching process. The protruding structure 222 is helpful for guiding cold air outside to flow into the chamber 218, and therefore heat can be spread more effectively.

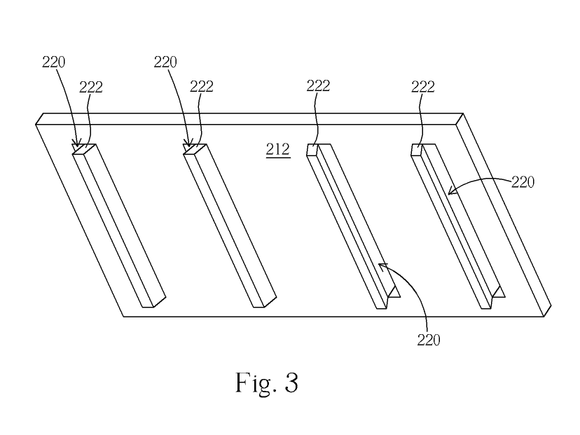

Please refer to FIG. 3. FIG. 3 shows a three-dimensional diagram of the heat spreader 212 shown in FIG. 2. As shown in FIG. 3, shapes of the openings 220 on the heat spreader 212 can be long narrow rectangles, and all the openings are parallel, but these are not limitations of the present invention.

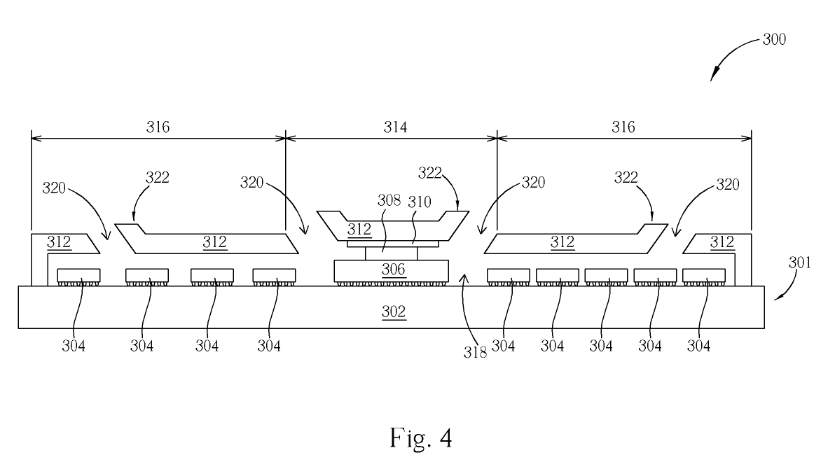

Please refer to FIG. 4. FIG. 4 shows a schematic, cross-sectional diagram illustrating a package device in accordance with a second preferred embodiment of the present invention. As shown in FIG. 4, the package device 300 includes a chip module 301 and a heat spreader 312, wherein the chip module 301 includes a first substrate 302, a plurality of first chips 304 and a second substrate 306 positioned on the first substrate 302, a second chip 308 positioned on the second substrate 306, and an adhesive layer 310 positioned on the second chip 308, and the heat spreader 312 has a prominent area 314 and a flat area 316. The prominent area 314 is positioned above the second substrate 306 and the adhesive layer 310, and the flat area 316 is positioned above the first substrate 302 and the first chips 304. The heat spreader 312 is connected to the second chip 308 via the adhesive layer 310, but the heat spreader 312 is not in touch with the first chips 304.

The chip module 301 can be an FBDIMM. The first substrate 302 can be a printed circuit board. The first chips 304 can be DRAM chips. The second substrate 306 can be an AMB substrate. The second chip 308 can be an AMB chip. The first chip 304 and the second substrate 306 can be electrically connected to the first substrate 302 via a BGA package, and the second chip 308 can be electrically connected to the second substrate 306 via a Flip Chip BGA package, but this is not a limitation of the present invention. Furthermore, the adhesive layer 310 can be a heat-spreading adhesive, and materials of the heat spreader 312 can be aluminum or copper.

Additionally, a chamber 318 is composed of the heat spreader 312 and the first substrate 302, and the chamber 318 contains the first chips 304, the second substrate 306, and the second chip 308. The present invention is characterized in that the heat spreader 312 has a plurality of openings 320 positioned above the first chips 304, and the openings 320 are used for cold air to flow into the chamber 318 and generate convection with hot air inside the chamber 318 in order to cool down the first chips 304 and the second chip 308.

The same side of each opening 320 on the heat spreader 312 has a protruding structure 322. The protruding structure 322 is formed during fabrication of the opening 320 by a punching process. The protruding structure 322 is helpful to guide cold air outside to flow into the chamber 318, and therefore heat can be spread more effectively.

Briefly summarized, the present invention fabricates the openings above the memory chips (i.e. the first chips 204 and 304), so cold air outside is able to flow into the package device and generate convection with hot air inside the package device during operation in order to cool down the memory chips and the whole package device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A package device, comprising:
a chip module, including a first substrate and at least a first chip on the first substrate; and
a heat spreader, covering the chip module and having a plurality of openings.

2. The package device of claim 1, wherein the chip module further comprising a second substrate having a second chip, and the second chip are connected to the heat spreader to form a chamber in the package device.

3. The package device of claim 1, wherein materials of the heat spreader comprise metal.

4. The package device of claim 1, wherein each of the openings has a protruding structure.

5. The package device of claim 1, wherein the chip module is a Fully Buffered Dual In-line Memory Module (FBDIMM).

6. The package device of claim 1, wherein the first chip is a Dynamic Random Access Memory (DRAM) chip.

7. The package device of claim 1, wherein the first substrate is a printed circuit board.

8. The package device of claim 2, wherein the second chip is an Advanced Memory Buffer (AMB) chip.

9. The package device of claim 2, wherein the second substrate is an Advanced Memory Buffer (AMB) substrate.

10. The package device of claim 2, wherein the second substrate and each first chip are electrically connected to the first substrate via a ball grid array (BGA) package, and the second chip is electrically connected to the second substrate via a Flip Chip BGA package.

11. A package device, comprising:
a printed circuit board, including a plurality of memory chips;
an Advanced Memory Buffer (AMB) substrate, connecting with the printed circuit board and having an Advanced Memory Buffer (AMB) chip on the AMB substrate; and
a heat spreader, covering the printed circuit board, wherein the heat spreader having a plurality of openings and a prominent area, and the prominent area is positioned above the AMB substrate and connected with the AMB chip by an adhesive layer.

12. The package device of claim 11, wherein materials of the heat spreader comprise metal.

13. The package device of claim 11, wherein the each of the openings has a protruding structure.

14. The package device of claim 11, wherein the AMB substrate and each memory chip are electrically connected to the printed circuit board via a ball grid array (BGA) package, and the AMB chip is electrically connected to the AMB substrate via a Flip Chip BGA package.

15. A heat spreading method for a package device, comprising:
providing a chip module; and
covering a heat spreader on the chip module to form a chamber in the package device, wherein the heat spreader including a plurality of openings and cold air outside the chamber is able to flow into the package device and generate convection with hot air inside the package device.
